(19) United States
(12) Patent Application Publication
(10) Pub. No.: US 2005/0215009 A1
(43) Pub. Date: Sep. 29, 2005

(54) Methods of forming phase-change memory devices

(76) Inventor: Sung-Lae Cho, Gyeonggi-do (KR)

Correspondence Address: MYERS BIGEL SIBLEY & SAJOVEC, PO BOX 37428, RALEIGH, NC, 27627, US

(21) Appl. No.: 11/084,274

(22) Filed: Mar. 18, 2005

(30) Foreign Application Priority Data
Mar. 19, 2004 (KR) 10-2004-0018968

(51) Int. Cl. H01L 21/00; H01L 21/336; G11B 5/33; G11B 5/127

(52) U.S. Cl. 438/257; 438/3

(57) ABSTRACT

A method of forming a phase-change non-volatile memory device can include etching-back a spacer insulating layer using a fluorine-based etch gas to form a spacer pattern in an opening in an interlayer dielectric layer and etching the spacer insulating layer in the opening using an inert gas.

### CROSS-REFERENCE TO RELATED APPLICATION

This application claims priority from Korean Patent Application No. 2004-18968, filed on Mar. 19, 2004, the content of which is herein incorporated by reference in its entirety.

### FIELD OF THE INVENTION

The invention generally relates to non-volatile memory devices and, more specifically, to methods of fabricating phase-change memory devices.

### BACKGROUND

Non-volatile memory devices are capable of storing data even with the power turned off. Generally, flash memory cells having a stacked gate structure are widely adapted to non-volatile memory devices. The stacked gate structure can include a tunnel oxide layer, a floating gate, an inter-gate dielectric layer and a control gate electrode, which are sequentially stacked over a channel region of the cell transistor. Accordingly, in order to improve the reliability and program efficiency of the flash memory cells, it may be beneficial to improve the film of the tunnel oxide layer and to increase the coupling ratio in the cell.

It is known to use non-volatile memory devices, such as phase-change memory devices, rather than the flash memory devices in non-volatile applications. An equivalent circuit of the phase-change memory cell is similar to that of a dynamic random access memory (DRAM) cell. In comparison, the DRAM cell stores information using capacitance, whereas a phase-change memory cell uses a variable resistance of a phase-change material to store/retrieve information. The phase-change material has two stable states as a function of temperature.

FIG. 1 is a graph illustrating programming and erasing of a conventional phase-change memory cell, where the abscissa represents time (T), and ordinate represents temperature (TMP) applied to the phase-change material. Referring to FIG. 1, when the phase-change material layer is heated and then cooled to a temperature higher than a melting temperature (Tm) during a first interval (T1), the state of the phase-change material takes on the amorphous state (1). When the phase-change material layer is heated and then cooled to a temperature less than the melting temperature (Tm) but greater than a crystallization temperature (Tc) during a second duration (T2) that is longer than the first duration (Ti), it takes on the crystalline state (2).

As is known, the resistivity of the phase-change material layer in the amorphous state is greater than the resistivity of the phase-change material layer in the crystalline state. Therefore, it is possible to discriminate whether information stored the phase-change memory cell is logically “1” or “0” by detecting a current in the phase-change material layer during a read mode. A compound material layer (hereinafter referred to as “GST layer”) containing Germanium (Ge), Tellurium (Te) and stibium (Sb) is widely used as the phase-change material layer.

As stated above, phase-change devices can be used to store/retrieve information based on a difference in resistance resulting from a phase-change in the material. A method of reducing contact area between a phase-change material and an electrode to cause a phase-change phenomenon employing small currents is discussed in U.S. Pat. No. 6,117,720, entitled in “METHOD OF MAKING AN INTEGRATED CIRCUIT ELECTRODE HAVING A REDUCED CONTACT AREA.”

FIG. 2 is a cross-sectional view showing a conventional phase-change memory device. The conventional phase-change memory device includes a lower electrode 12 formed on a semiconductor substrate 10 and an interlayer dielectric layer 14 having an opening on the lower electrode 12. A spacer 16 is formed on the sidewalls of the opening, and a phase-change pattern 18 connected to the lower electrode 12 is located in the opening and on the spacer 16. The lower electrode 14 may be formed of titanium nitride TiN, tantalum aluminum nitride TaAlN, titanium silicon nitride TiSiN, tantalum aluminum nitride TaAlN, or tantalum silicon nitride TaSiN Referring to FIG. 3, after conformally forming a spacer insulating layer on the interlayer dielectric layer 14 having the opening, the spacer insulating layer may be formed by an etch-back of the spacer insulating layer. The spacer insulating layer may be formed of a silicon oxide SiO₂, silicon nitride SiₓN_{y} or silicon oxynitride SiON. In addition, the spacer insulating layer may be anisotropically etched using a fluorine based gas (e.g., CF₄, C₂F₆, CHF₃, NF₃, SF₄, and C₄ μg).

In order to prevent the spacer insulating layer from completely covering the lower electrode 12 in the opening, an over-etch can be performed using a fluorine based etch gas after forming the spacer 16. In accordance with the conventional art, a metal-fluorine polymer may be formed at the edge of the spacer 16 during the over-etch from a reaction between the fluorine based etch gas and the metal of the lower electrode. As a result, the profile of the spacer 16 may be non-uniform, which may adversely affect the shape of the spacers in the opening. Moreover, the area of a phase-change layer that is in contact with the lower electrode 14 may be non-uniform, which may cause large variations in the characteristics of the cells in the device. In addition, the metal-fluorine polymer may contaminate subsequent processing.

### SUMMARY

Embodiments according to the invention can provide methods of forming phase-change memory devices. Pursuant to these embodiments, a method of forming a phase-change non-volatile memory device can include etching-back a spacer insulating layer using a fluorine-based etch gas to form a spacer pattern in an opening in an interlayer dielectric layer and etching the spacer insulating layer in the opening using an inert gas.

In some embodiments according to the invention, the inert gas is an inert gas plasma. In some embodiments according to the invention, the method can also include forming a phase-changeable layer in the opening. In some embodiments according to the invention, the method can also include forming the spacer insulating layer on the interlayer dielectric layer including conformally in the opening.

In some embodiments according to the invention, the method can also include forming the interlayer dielectric layer to a thickness of about 800 Å or less. In some embodiments according to the invention, the method can also include forming the spacer insulating layer to a thickness based on a diameter of the opening. In some embodiments according to the invention, forming the spacer insulating layer can include forming the spacer insulating layer thinner than a radius of the opening.

In some embodiments according to the invention, forming the spacer insulating layer can include forming the spacer insulating layer thinner than the interlayer dielectric layer. In some embodiments according to the invention, the method can also include forming the interlayer dielectric layer to a thickness less than about 800 Å and more than a thickness of the spacer insulating layer.

In some embodiments according to the invention, etching-back a spacer insulating layer can include etching-back the spacer insulating layer until a lower electrode is exposed beneath the spacer insulating layer. In some embodiments according to the invention, a portion of the spacer insulating layer remains on the exposed lower electrode. In some embodiments according to the invention, etching the spacer insulating layer in the opening using an inert gas can include etching the spacer insulating layer using Argon gas.

In some embodiments according to the invention, a method of forming a phase-change non-volatile memory device can include forming a lower electrode layer in a phase-change non-volatile memory device on a substrate. An interlayer dielectric layer is formed on the lower electrode layer. An opening is formed in the interlayer dielectric layer. A spacer insulating layer is formed on the interlayer dielectric layer and conformally in the opening. The spacer insulating layer is etched-back using a fluorine-based etch gas to form a spacer pattern in the opening to expose at least a portion of the lower electrode. The spacer insulating layer is etched using an inert gas to remove a remaining portion of the spacer insulating layer from the opening; A phase-changeable layer is formed in the opening.

In some embodiments according to the invention, forming the interlayer dielectric layer includes forming the interlayer dielectric layer to a thickness about equal to or less than about 800 Å and more than a thickness of the spacer insulating layer.

In some embodiments according to the invention, a method of forming a phase-change non-volatile memory device can include forming a metallic lower electrode on a substrate. An interlayer dielectric layer is formed having an opening that exposes the metallic lower electrode on the substrate. A spacer insulating layer is conformally formed on the interlayer dielectric layer. The spacer insulating layer is etched-back using a plasma including a fluorine-based gas to form a spacer pattern inner sidewall in the opening and to expose the metallic lower electrode in a region in the opening covered with the spacer pattern. The spacer insulating layer is over-etched using an inert gas plasma. A phase-changeable layer is formed in the opening.

In some embodiments according to the invention, the metallic lower electrode reacts with the fluorine-based gas to form a non-volatile metal-fluorine based by-product in the opening. In some embodiments according to the invention, the metallic lower electrode includes titanium, titanium nitride, titanium aluminum nitride, tantalum and/or tantalum nitride. In some embodiments according to the invention, the interlayer dielectric layer is formed thicker than the spacer insulating layer and an interlayer dielectric layer is formed to a thickness of about 800 Å or less.

In some embodiments according to the invention, the fluorine-based etch gas is CF₄, C₂F₆, CHF₃, NF₃, SF₄, and/or C₄F₈. In some embodiments according to the invention, etching-back is ceased when the metallic lower electrode is exposed, and wherein a residual spacer insulating layer in the region covered with the spacer pattern is removed by the over-etching.

### BRIEF DESCRIPTION OF THE DRAWINGS

FIG. 1 is a graph illustrating a method of programming and erasing a phase-change memory device.

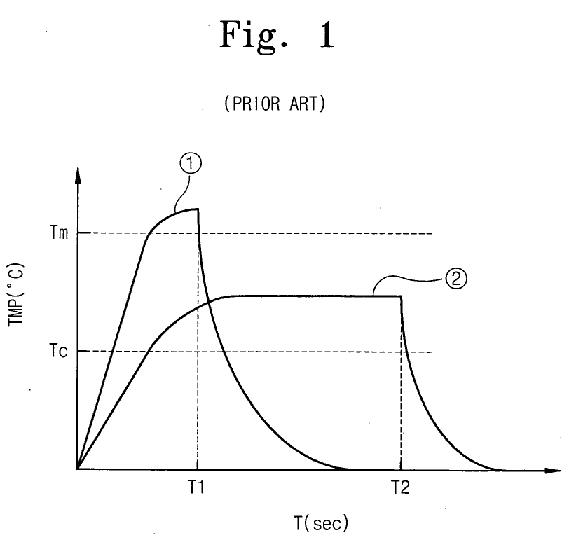

FIG. 2 is a cross-sectional view showing a conventional phase-change memory device.

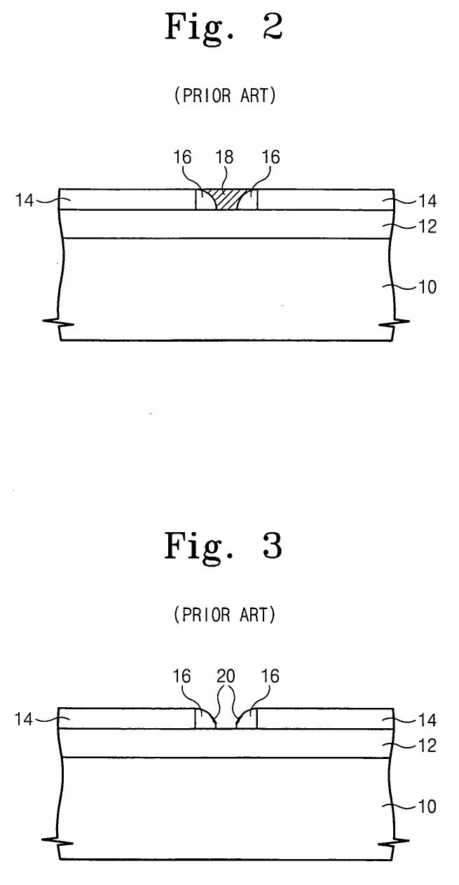

FIG. 3 illustrates a problem of the conventional phase-change memory device.

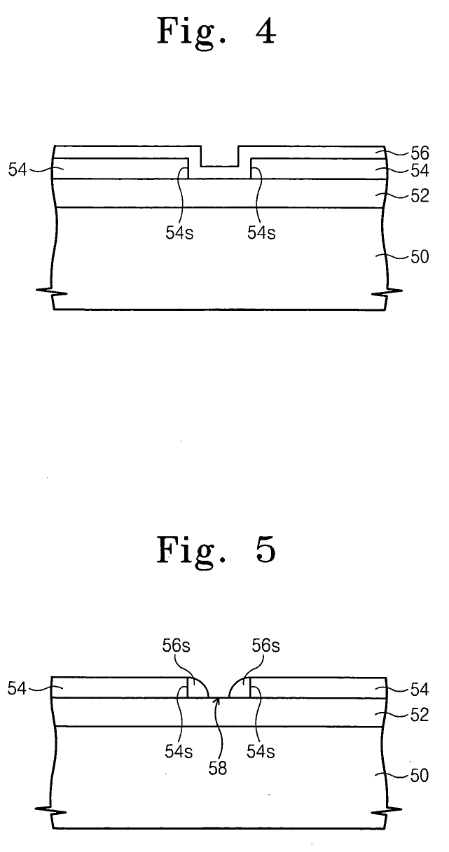

FIGS. 4 to 7 are procedural section views illustrating a method of fabricating the phase-change memory device in accordance with a preferred embodiment of the present invention.

### DETAILED DESCRIPTION OF EMBODIMENTS ACCORDING TO THE INVENTION

The present invention will be described more fully hereinafter with reference to the accompanying drawings, in which exemplary embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. All publications, patent applications, patents, and other references mentioned herein are incorporated by reference in their entirety.

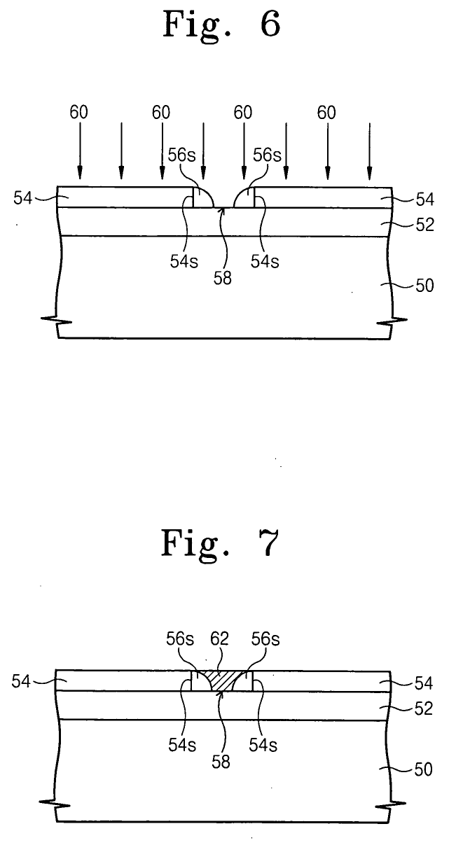

FIGS. 4 to 7 are cross-sectional views illustrating methods of fabricating phase-change memory devices in some embodiments according to present invention. Referring to FIG. 4, a lower electrode 52 is formed on a semiconductor substrate 50. Although not shown, the lower electrode 52 is connected to a source/drain of an access transistor of a phase-change cell on the semiconductor substrate 50. In some embodiments according to the invention, the lower electrode 52 includes titanium, titanium nitride, tantalum, and/or tantalum nitride.

It is well known that the above materials may react with fluorine based etch gases to generate a non-volatile metal-fluorine based by-product. The lower electrode 52 is not limited to the above materials, and may be formed of a conductive material suitable for a phase-change memory device. In this case, if the conductive material is reacted with etch gases to generate a non-volatile metal-fluorine based by-product, the effect the present invention can be doubled.

An interlayer dielectric layer 54 is formed on an entire surface of the substrate 50 on which the lower electrode 52 is formed. The interlayer dielectric layer 54 is patterned to form an opening 54s to expose a portion of the lower electrode 52. A spacer insulating layer 56 is conformally formed on the interlayer dielectric layer 54 including in the opening 54s. In some embodiments according to the invention, the spacer insulating layer 56 is formed of silicon nitride and/or silicon oxide.

If the interlayer dielectric layer 54 is relatively thick, the opening 54s may have a relatively large aspect ratio (i.e., relatively narrow and deep), especially if the phase-change memory device is highly integrated (i.e., the opening is relatively small). The large aspect ratio may contribute to the opening not being completely filled in a subsequent process. Accordingly, it is preferable that the thickness of the interlayer dielectric layer 54 does not exceed about 800 Å.

In some embodiments according to the invention, the spacer insulating layer 56 is formed to have an opening with diameter under a limitation to be delimited in a photolithography process. In other words, the thickness of the spacer insulating layer 56 may be selected in view of the diameter of the opening 54s (if the opening 54s is to have a relatively small diameter). In some embodiments according to the invention, the spacer insulating layer 56 is thinner than a radius (i.e., half the diameter) of the opening 54s.

It is also preferable that the spacer insulating layer 56 be thinner than the interlayer dielectric layer 54. In particular, if the spacer insulating layer 56 were to be thicker than the interlayer dielectric layer 54, it may be difficult to form a spacer on sidewalls of the opening 54s in a subsequent process. It is preferable that the thickness of the interlayer dielectric layer 54 be less than about 800 Å and be thicker than the spacer insulating layer 56.

Referring to FIG. 5, the spacer insulating layer 56 is etched-back to form a spacer pattern 56s on the inner sidewalls of the opening 54s. The spacer insulating layer 56 may be anisotropically etched using a plasma containing fluorine based etch gases. In other words, the spacer insulating layer 56 may be etched using a plasma (e.g., CF₄, C₂F₆, CHF₃, NF₃, SF₄, and C₄F₈). In some embodiments according to the invention, the etch-back process is stopped before forming a non-volatile metal-fluorine based by-product (from the reaction of the fluorine based etch gases and the lower electrode). In some embodiments according to the invention, the etch-back is stopped at a point where the lower electrode 52 is exposed. In some embodiments according to the invention, a portion of the spacer insulating layer may remain on a lower electrode 58 exposed at a region covered with the spacer pattern 56s.

According to some conventional approaches, if an over-etch is performed to remove the residual insulating layer from the opening, a non-volatile metal-fluorine based by-product may adhere to the spacer pattern. In order to reduce a contact area between a phase-change material and a lower electrode, it is preferable that the width of the spacer pattern be maximized. However, if the spacer insulating layer is formed on the interlayer dielectric layer to a thickness less than 800 Å, the slope of the spacer pattern may be gentle (i.e., shallow). Since a metal-fluorine based by-product may adhere to this structure, an exposure surface of the lower electrode may be dramatically transformed by the by-product. In contrast to the conventional art, in accordance with some embodiments of the present invention, the lower electrode may be etched relatively little by the etch gases based fluorine.

Referring to FIG. 6, the structure in the opening (including the spacer pattern 56s) is over-etched using an inert gas plasma 60 (e.g., Ar), so that the residual spacer insulating layer on a contact portion between the lower electrode and the phase-change material may be more completely removed. Because the inert gas plasma 60 is less likely to generate a non-volatile by-product from a reaction with the metal of the lower electrode 52, a by-product is not left on the spacer pattern 56s, and also the shape of the contact portion may not be transformed.

Referring to FIG. 7, a phase-change material 62 is deposited in the opening including the spacer pattern 56s. Resultantly, a contact surface between the phase-change material 62 and the lower electrode 52 may be more consistent from cell to cell in the non-volatile memory device, so that a dispersion of a contact surface in a phase-change memory cell array may be conformal.

In some embodiments according to the invention, since an over-etch process is performed using an inert gas, a metal-fluorine based non-volatile by-product may not be generated, thereby allowing an improvement in the uniformity of contact surfaces (from cell to cell) between the phase-change material and the lower electrode. In accordance with embodiments according to the invention, since a contact surface between a lower electrode and a phase-change material is conformal, it is possible to allow more uniformity in the cell characteristics of a phase-change memory device.

Changes can be made to the invention in light of the above detailed description. In general, in the following claims, the terms used should not be construed to limit the invention to the specific embodiments disclosed in the specification and the claims, but should be construed to include all methods and devices that are in accordance with the claims. Accordingly, the invention is not limited by the disclosure, but instead its scope is to be determined by the following claims.

1. A method of forming a phase-change non-volatile memory device comprising:
etching-back a spacer insulating layer using a fluorine-based etch gas to form a spacer pattern in an opening in an interlayer dielectric layer; and
etching the spacer insulating layer in the opening using an inert gas.

2. A method according to claim 1 wherein the inert gas comprises an inert gas plasma.

3. A method according to claim 1 further comprising:
forming a phase-changeable layer in the opening.

4. A method according to claim 1 further comprising:
forming the spacer insulating layer on the interlayer dielectric layer including conformally in the opening.

5. A method according to claim 1 further comprising:
forming the interlayer dielectric layer to a thickness of about 800 Å or less.

6. A method according to claim 1 further comprising:
forming the spacer insulating layer to a thickness based on a diameter of the opening.

7. A method according to claim 6 wherein forming the spacer insulating layer comprises forming the spacer insulating layer thinner than a radius of the opening.

8. A method according to claim 6 wherein forming the spacer insulating layer comprises forming the spacer insulating layer thinner than the interlayer dielectric layer.

9. A method according to claim 1 further comprising:
forming the interlayer dielectric layer to a thickness less than about 800 Å and more than a thickness of the spacer insulating layer.

10. A method according to claim 1 wherein etching-back a spacer insulating layer comprises etching-back the spacer insulating layer until a lower electrode is exposed beneath the spacer insulating layer.

11. A method according to claim 10 wherein a portion of the spacer insulating layer remains on the exposed lower electrode.

12. A method according to claim 1 wherein etching the spacer insulating layer in the opening using an inert gas comprises etching the spacer insulating layer using Argon gas.

13. A method of forming a phase-change non-volatile memory device comprising:
forming a lower electrode layer in a phase-change non-volatile memory device on a substrate;
forming an interlayer dielectric layer on the lower electrode layer;
forming an opening in the interlayer dielectric layer;
forming a spacer insulating layer on the interlayer dielectric layer and conformally in the opening;
etching-back the spacer insulating layer using a fluorine-based etch gas to form a spacer pattern in the opening to expose at least a portion of the lower electrode;
etching the spacer insulating layer using an inert gas to remove a remaining portion of the spacer insulating layer from the opening; and
forming a phase-changeable layer in the opening.

14. A method according to claim 13 wherein forming the interlayer dielectric layer comprises forming the interlayer dielectric layer to a thickness about equal to or less than about 800 Å and more than a thickness of the spacer insulating layer.

15. A method of fabricating a phase-change memory device comprising:
forming a metallic lower electrode on a substrate;
forming an interlayer dielectric layer having an opening that exposes the metallic lower electrode on the substrate;
conformally forming a spacer insulating layer on the interlayer dielectric layer;
etching-back the spacer insulating layer using a plasma including a fluorine-based gas to form a spacer pattern inner sidewall in the opening and to expose the metallic lower electrode in a region in the opening covered with the spacer pattern;
over-etching the spacer insulating layer using an inert gas plasma; and
forming a phase-changeable layer in the opening.

16. A method according to claim 15 wherein the metallic lower electrode reacts with the fluorine-based gas to form a non-volatile metal-fluorine based by-product in the opening.

17. A method according to claim 16 wherein the metallic lower electrode includes titanium, titanium nitride, titanium aluminum nitride, tantalum and/or tantalum nitride.

18. A method according to claim 15 wherein the interlayer dielectric layer is formed thicker than the spacer insulating layer; and
wherein forming an interlayer dielectric layer comprises forming the interlayer dielectric layer to a thickness of about 800 Å or less.

19. A method according to claim 15 wherein the fluorine-based etch gas comprises CF₄, C₂F₆, CHF₃, NF₃, SF₄, and/or C₄F₈.

20. A method according to claim 15 wherein etching-back is ceased when the metallic lower electrode is exposed, and wherein a residual spacer insulating layer in the region covered with the spacer pattern is removed by the over-etching.
